(19) United States
(12) Patent Application Publication
(10) Pub. No.: US 2014/0185261 A1
(43) Pub. Date: Jul. 3, 2014

(54) SCREEN DISPLAY FIXTURE

(71) Applicant: Mao-Sung Wu, (US)

(72) Inventors: MAO-SUNG WU, TAOYUAN (TW); Chen-Hao Chu, TAOYUAN (TW)

(73) Assignee: MAO-SUNG WU, TAOYUAN (TW)

(21) Appl. No.: 13/795,549

(22) Filed: Mar. 12, 2013

(30) Foreign Application Priority Data
Jan. 3, 2013 (TW) 102200065

(51) Int. Cl. H05K 5/02

(52) U.S. Cl. CPC H05K 5/0217
USPC 361/809

(57) ABSTRACT

Disclosed is a fixture including at least two holding portions having an opening formed between ends of two holding portions, an elastic connecting portion coupled to the two holding portions, a containing space formed between the two holding portions and the elastic connecting portion, and the opening being smaller than the containing space, and a protective layer formed on a surface opposite to the ends of the two holding portions. The fixture can clamp and hold other objects such as a screen protector, a filter glass or an external touch panel onto a display screen and achieve a protection effect by the protective layer of the holding portion.

### FIELD OF THE INVENTION

The present invention relates a display screen fixture, and more particularly to the display screen fixture capable of clamping other objects on a display screen.

### DESCRIPTION OF RELATED ART

As computers become increasingly more popular and mature, display devices are switched from traditional monitor screens to LED screens, but manufacturers further develop touch screens for a more convenient use and a better effect. Since the traditional computers require using a mouse to click an icon to execute an operation, but the touch screens requires no additional peripheral such as the mouse to operate the screen, therefore users simply need to touch the screen to achieve the same effect of controlling a mouse cursor. The operation of touch screen not only reduces the occupied space, but also allows users to put the computers at a place more flexibly. With the simple operation, the elderly or children who cannot execute detailed operations or are not familiar with the operation of a mouse can learn how to use the touch screen easily and operate the computer intuitively.

Regardless of a resistive touch screen or a capacitive touch screen, expensive components including a touch panel and a touch chip are required, and present existing computers are generally equipped with a screen. If the original screen is still working and the screen is changed to a touch screen, it will cause an unnecessary waste of resources and environmental issues in addition to a higher cost.

To overcome the aforementioned problems, an external touch device is introduced, wherein the external touch device is attached onto a computer screen by a connecting device such as a Velcro tape, a hook or a bolt. However, the Velcro tape fails to give a secured connection and requires an adhesive attached onto the back of the screen that results in a poor look; the hook is hanged on the screen, so that the screen may be shaken and unable to be used easily, and it also has the disadvantages of a poor appearance, an inconvenient carry due to the screws used for fixing the hook, and a risk of scratching the screen. In addition, some of the external touch devices are exposed from the structure and may injure the users easily, and the external control circuit may be damaged by environmental factors such as humidity.

In the conventional external touch panels as disclosed in R.O.C. Pat. No. 510632 entitled “External touch filter glass”, R.O.C. Pat. No. M379803 entitled “External touch panel” and R.O.C. Pat. No. M375933 entitled “External touch input device”, the aforementioned Velcro tape, hook or bolt used as a connecting device has the drawbacks as mentioned above.

Therefore, it is a main subject for related manufactures to provide a portable touch panel with a simple structure, an easy installation or removal, and a convenient carry without damaging the structure of the screen and a touch control function for computers particularly for notebook computers.

### SUMMARY OF THE INVENTION

In view of the aforementioned problems of the prior art, it is a primary objective of the present invention to provide a fixture of a display screen for clamping outer objects on the display screen.

To achieve the aforementioned objective, the present invention provides a fixture comprising: at least two holding portions, having an opening formed between respective ends of the holding portions; an elastic connecting portion, coupled to the two holding portions; a containing space, defined between the two holding portions and the elastic connecting portion, and having a size greater than the opening; and a protective layer, separately formed on opposite surfaces at the ends of the two holding portions.

Wherein, the fixture can clamp other objects such as a screen protector, a filter glass or an external touch panel onto the display screen and achieve a protection effect by the protective layer of the holding portion which is in contact with the screen protector of the external touch panel.

### BRIEF DESCRIPTION OF THE DRAWINGS

FIG. 1 is a perspective view of a fixture in accordance with a first embodiment of the present invention;

FIG. 2 is a schematic view of a fixture in accordance with the first embodiment of the present invention;

FIG. 3 is a perspective view of an operation of a fixture in accordance with the first embodiment of the present invention;

FIG. 4 is a schematic view of an operation of a fixture in accordance with the first embodiment of the present invention;

FIG. 5 is a schematic view of a fixture in accordance with a second embodiment of the present invention;

FIGS. 6A and 6B are schematic views of a fixture in accordance with a third preferred embodiment of the present invention;

FIGS. 7A and 7B are schematic views of a fixture in accordance with a fourth preferred embodiment of the present invention;

FIGS. 8A and 8B are schematic views of a fixture in accordance with a fifth preferred embodiment of the present invention; and

FIG. 9 is it schematic view of a fixture in accordance with a sixth preferred embodiment of the present invention.

### DETAILED DESCRIPTION OF THE PREFERRED EMBODIMENTS

The technical contents of the present invention will become apparent with the detailed description of preferred embodiments and the illustration of related drawings as follows.

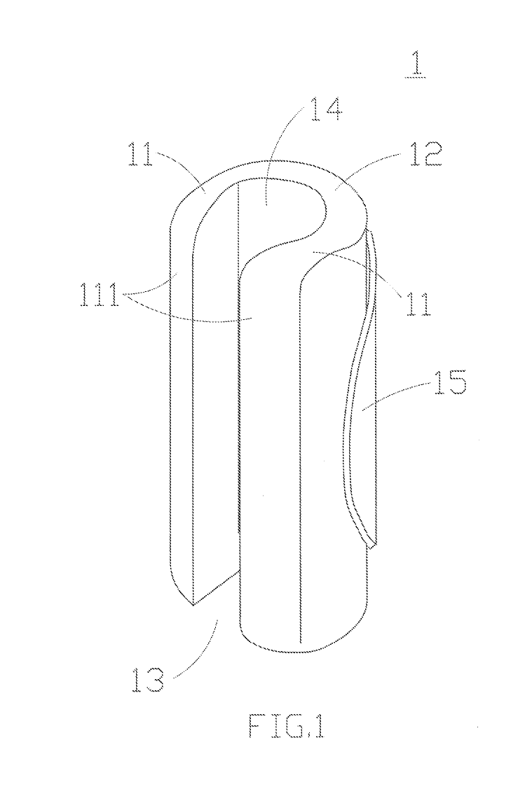

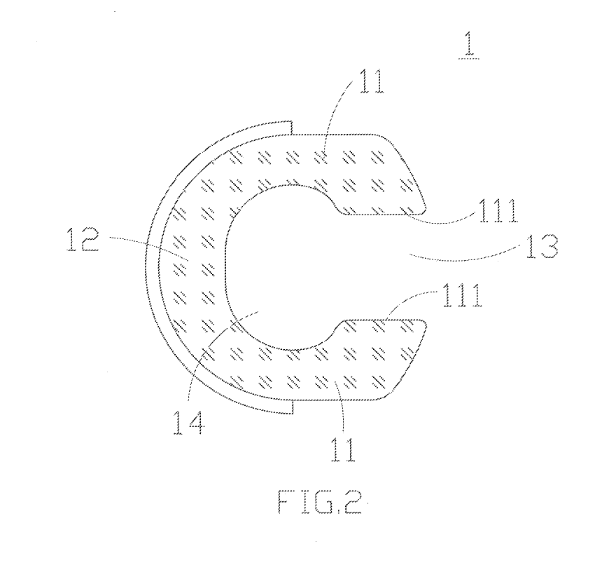

With reference to FIGS. 1 and 2 for a perspective view and a schematic view of a fixture of a display screen in accordance with the first embodiment of the present invention respectively, the fixture 1 comprises at least two holding portions 11, and an elastic connecting portion 21 coupled to the two holding portions 11. In the preferred embodiment as shown in FIGS. 1 and 2, the fixture is a C-shaped structure, and an opening 13 is formed between ends of the two holding portions 11, and a containing space 14 is formed between the two holding portions 11 and the elastic connecting portion 12, wherein the opening 13 is smaller than the containing space 14, and a protective layer 111 is formed on a surface opposite to an end of each of the two holding portions 11.

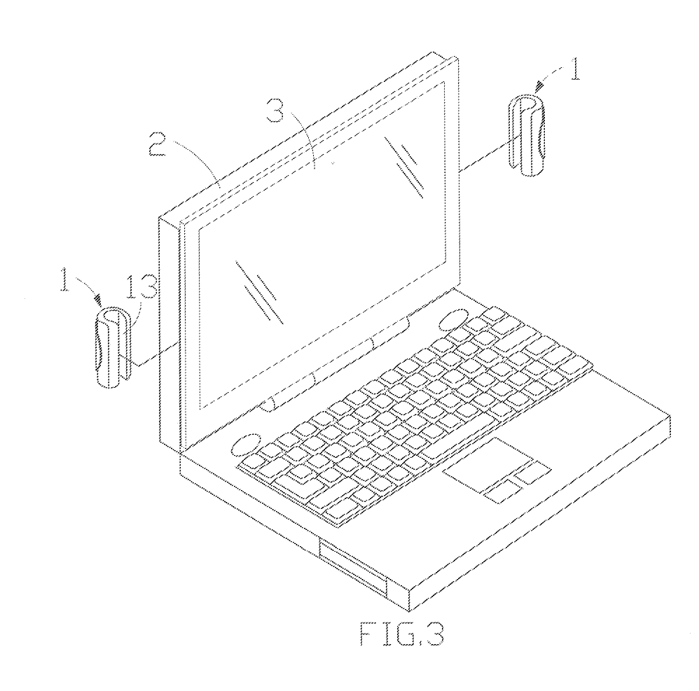

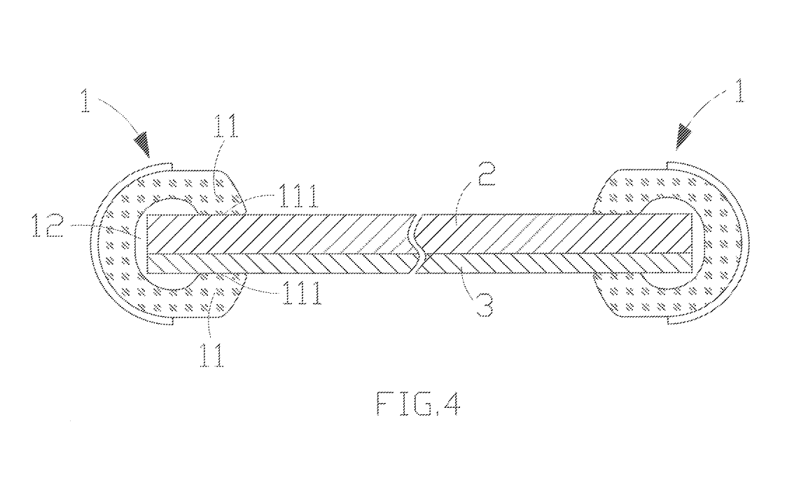

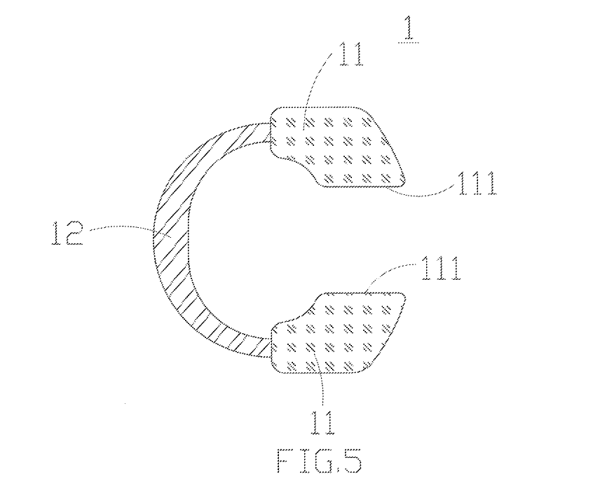

During use, the fixture clamps an object such as a screen protector, a filter glass or an external touch panel onto the display screen. In the preferred embodiment as shown in FIGS. 3 and 4, the fixture 1 clamps an external touch panel 3 onto a display screen 2, wherein the external touch panel 3 is placed near a desired fixing position of the display screen 2, and the elasticity of elastic connecting portion 12 spreads the two holding portions 11 slightly open to set the opening 13 and the containing space 14 to be latched with ends of the display screen 2 and the external touch panel 3, and the two holding portions 11 are provided for clamping the surfaces of the display screen 2 and the external touch panel 3 to achieve the effect of fixing the two, and the protective layer 111 of the holding portion is in contact with the display screen 2 and the external touch panel 3 to achieve the protection effect. Of course, a plurality of fixtures can be used as needed to clamp the display screen and the external touch panel and enhance the fixing effect.

Wherein, the fixture can be integrally formed and made of rubber. In other words, the two holding portions, the protective layer and the elastic connecting portion are made of rubber. The elastic connecting portion 12 further has a decorative layer 15 disposed on a surface opposite to the of the other side of the containing space 14 as shown in FIG. 1 to provide a different decoration effect, or the two holding portions 11 and the protective layer 111 are made of rubber. In the second preferred embodiment as shown in FIG. 5, the elastic connecting portion 12 is made of metal, the protective layer is made of foam or plastic, and the elastic connecting portion is made of plastic.

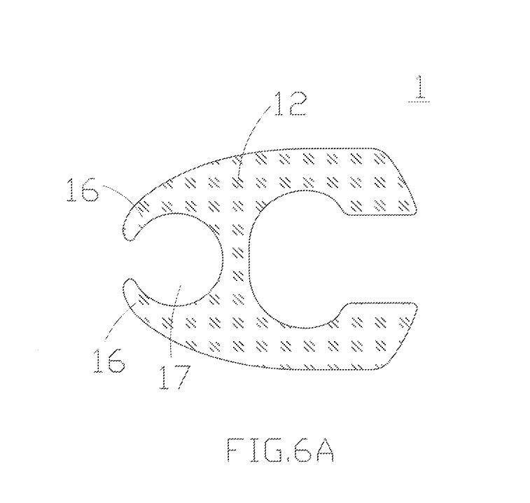

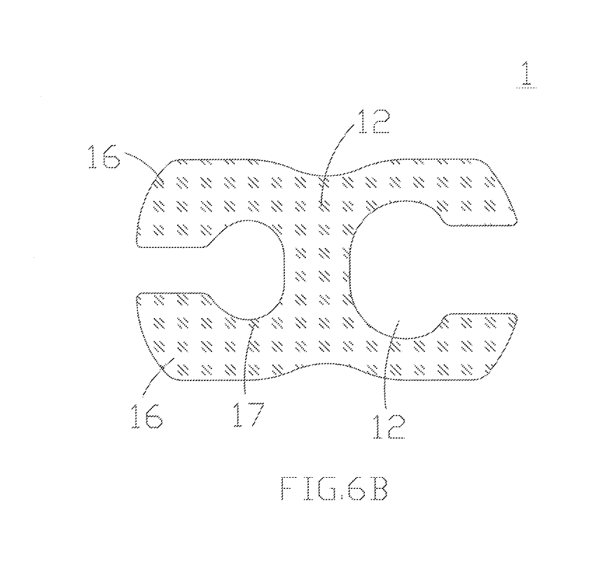

In addition, the elastic connecting portion further has a secondary containing space disposed opposite to the other side of the containing space for clamping other objects as shown in FIGS. 6(A) and 6(B), and the elastic connecting portion 12 has two secondary holding portions 16 extended towards the other side, and the secondary containing space 17 is defined between the two secondary holding portions 16 and the elastic connecting portion 12, and a secondary opening 18 is defined between the two secondary holding portions 16, wherein the secondary opening 18 is smaller than the secondary containing space 17 and provided for clamping or holding other objects such as a touch pen.

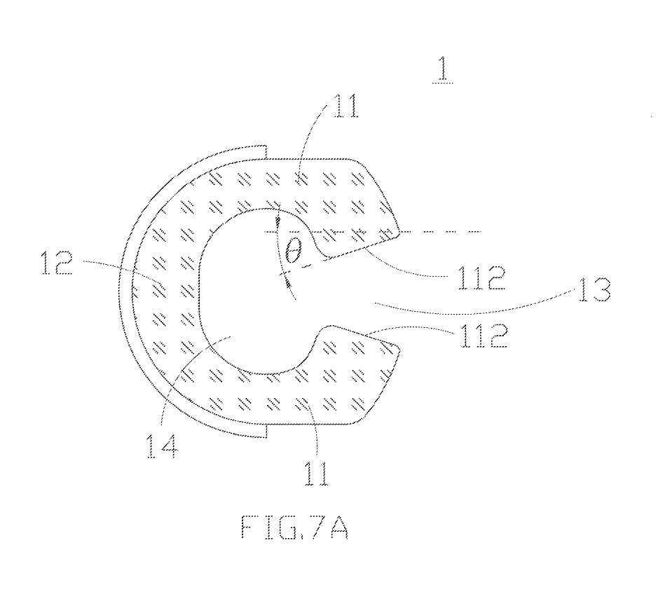

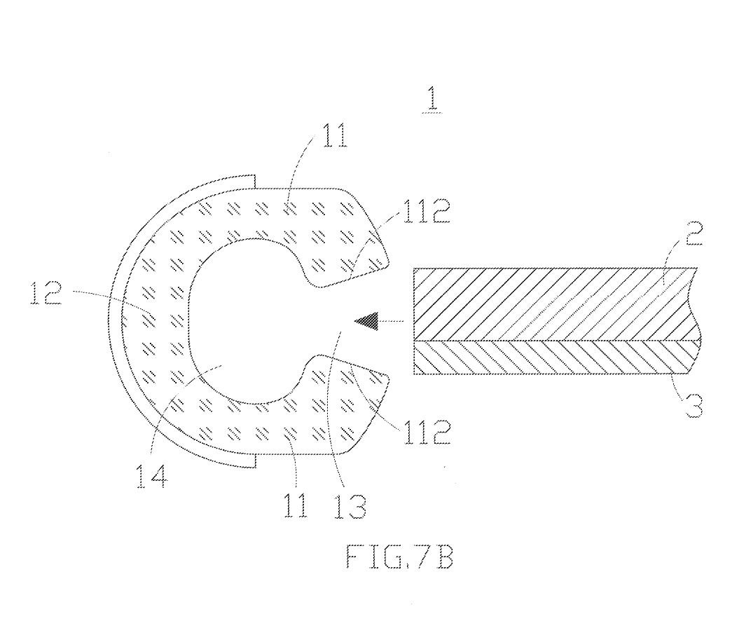

In the fourth preferred embodiment as shown in FIG. 7(A), a bevel 112 is formed on a surface opposite to an end of each of the two holding portions 11, and an opening 13 is formed between the bevels 112 of the two holding portions and tapered inwardly. Wherein, the bevel 112 has an angle of inclination (θ) falling within a range of 0˜20 degrees, preferably within a range of 10˜15 degrees, and the bevels 112 of the two holding portions can have different angles of inclination. Of course, the bevels of the two holding portions can have different angles of inclination.

When the fixture 1 clamps an object (such as an external touch panel 3) onto the display screen 2 as shown in FIG. 7 (B), the opening 13 is expanded to facilitate users to clamp the display screen 2 and the external touch panel 3 for a convenient operation.

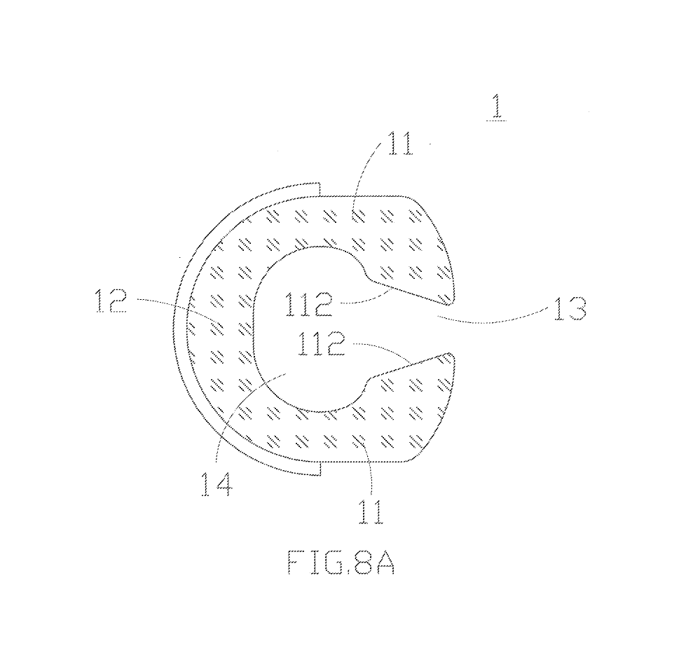

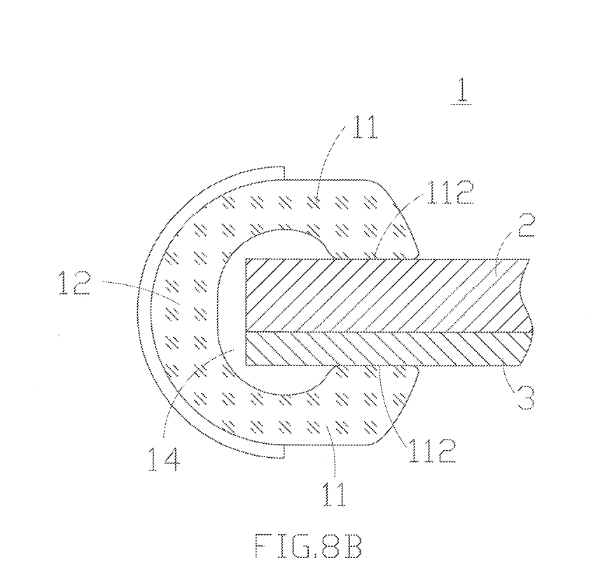

In the fifth preferred embodiment as shown in FIG. 8(A), an opening is formed between the bevels 112 of the two holding portions and tapered inwardly. When the external touch panel 3 is clamped onto the display screen 2 as shown in FIG. 8(B), the elastic connecting portion 12 spreads the opening 13 open to allow the bevels 112 of the two holding portions to be attached and contacted with a surface of the display screen 2 or the external touch panel 3, so as to enhance the contact area between the two holding portions 11, the display screen 2 and the external touch panel 3 and improve the stability and reliability of clamping the object.

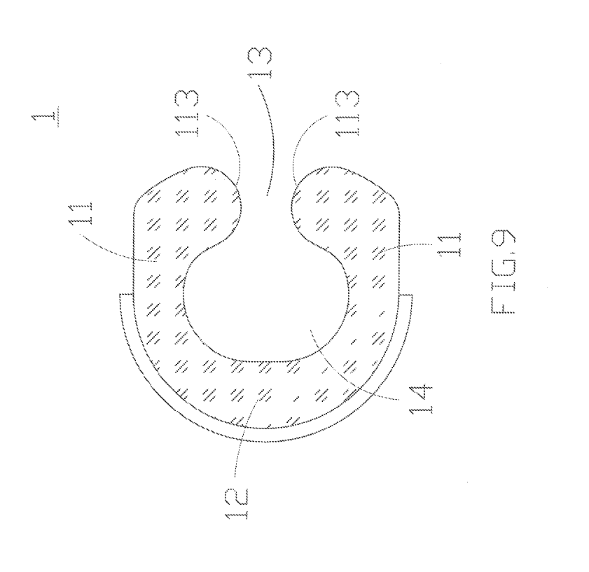

With reference to FIG. 9 for the sixth preferred embodiment of the present invention, a cambered surface 113 is defined on a surface opposite to an end of each of the two holding portions 11. Similarly, other objects can be clamped and held onto the display screen by the two holding portions 11.

Compared with the prior art, the present invention has the following advantages:

1. The fixture of the present invention not only features a simple structure, an easy installation or removal, and a convenient carry, but it also maintains a good look of the computer without scratching the computer or the display screen. In addition, the external touch panel can be installed on a general display screen, so that the display screen has the touch control function.

2. The holding portion of the fixture has a protective layer (made of rubber) to provide a protection effect and prevent scratching the computer or the display screen when the object is clamped.

While the invention has been described by means of specific embodiments, numerous modifications and variations could be made thereto by those skilled in the art without departing from the scope and spirit of the invention set forth in the claims.

What is claimed is:

1. A display screen fixture, comprising:
at least two holding portions, having an opening formed between respective ends the holding portions;
an elastic connecting portion, coupled to the two holding portions;
a containing space; defined between the two holding portions and the elastic connecting portion, and having a size greater than the opening; and
a protective layer, separately formed on opposite surfaces at the ends of the two holding portions.

2. The display screen fixture of claim 1, wherein the two holding portions and a protective layer thereof are made of rubber, and the elastic connecting portion is made of metal.

3. The display screen fixture of claim 1, wherein the two holding portions and a protective layer and an elastic connecting portion thereof are made of rubber.

4. The display screen fixture of claim 1, wherein the elastic connecting portion further has a secondary containing space formed on another side opposite to the containing space.

5. The display screen fixture of claim 4, wherein the elastic connecting portion has two secondary holding portions extended towards the other side, and the two secondary holding portions and the elastic connecting portion define the secondary containing space.

6. The display screen fixture of claim 5, further comprising a secondary opening formed between the two secondary holding portions and being smaller than the secondary containing space.

7. The display screen fixture of claim 1, wherein the elastic connecting portion further includes a decorative layer disposed on a surface opposite to the other side of the containing space.

8. The display screen fixture of claim 1, wherein the protective layer is made of foam.

9. The display screen fixture of claim 1, wherein the elastic connecting portion is made of plastic.

10. A display screen fixture, comprising:
at least two holding portions, having an opening formed between ends of the two holding portions;
an elastic connecting portion, coupled to the two holding portions;
a containing space, formed between the two holding portions and the elastic connecting portion, and having a size greater than the opening;
a protective layer, formed on a surface opposite to ends of the two holding portions; and
a bevel, defined on a surface opposite to an end of each of the two holding portions;
wherein an opening formed between the bevels of two holding portions is tapered inwardly.

11. The display screen fixture of claim 10, wherein the elastic connecting portion is provided for spreading the opening to open outwardly to allow the bevels of the two holding portions to be attached or contacted with a surface of the display screen or the object, when the fixture clamps an object onto a display screen.

12. The display screen fixture of claim 10, wherein the bevel preferably has an angle of inclination falling within a range of 0˜20 degrees.

13. The display screen fixture of claim 12, wherein the bevel of the two holding portions preferably has an angle of inclination falling within a range of 10˜15 degrees.

14. A display screen fixture, comprising:
at least two holding portions, having an opening formed between ends of the two holding portions;
an elastic connecting portion, coupled to the two holding portions;
a containing space, formed between the two holding portions and the elastic connecting portion, and having a size greater than the opening;
protective layer, formed on a surface opposite to an end of each of the two holding portions; and
a bevel, defined on a surface opposite to an end of each of the two holding portions;
wherein an opening formed between the bevels of the two holding portion is tapered inwardly.

15. The display screen fixture of claim 11, wherein the bevel preferably has an angle of inclination falling within a range of 0˜20 degrees.

16. The display screen fixture of claim 15, wherein the bevel of the two holding portions preferably has an angle of inclination falling within a range of 10˜15 degrees.

17. A display screen fixture, comprising:
at least two holding portions, having an opening formed between ends of the two holding portion;
an elastic connecting portion, coupled to the two holding portions;
a containing space, formed between the two holding portions and the elastic connecting portion, and having a size greater than the opening;
a protective layer, formed on a surface opposite to an end of each of the two holding portions; and
a cambered surface, defined on a surface opposite to an end of each of the two holding portions.
